(19) United States
(12) Patent Application Publication
(10) Pub. No.: US 2019/0229220 A1
(43) Pub. Date: Jul. 25, 2019

(54) IMAGE PICKUP DEVICE AND DISPLAY DEVICE

(71) Applicant: CANON KABUSHIKI KAISHA, Tokyo (JP)

(72) Inventor: Koichi Tazoe, Sagamihara-shi (JP)

(21) Appl. No.: 16/232,418

(22) Filed: Dec. 26, 2018

(30) Foreign Application Priority Data
Jan. 24, 2018 (JP) 2018-009558

(51) Int. Cl. H01L 31/0203; H01L 27/146; G06T 7/55

(52) U.S. Cl. CPC H01L 31/0203; H01L 27/14636; H01L 27/307; G06T 7/55; H01L 27/1462

(57) ABSTRACT

Provided is an image pickup device including: a semiconductor substrate including a pixel region in which pixels are arranged and a pad electrode region on which a pad electrode portion is disposed; a wiring layer formed on the semiconductor substrate and including the pad electrode portion; a planarizing layer formed on the wiring layer and formed in a portion upper than the pad electrode portion in the pad electrode region, the planarizing layer including an organic material; and an inorganic film formed on the planarizing layer. An opening having a side wall portion is formed in the planarizing layer and the inorganic film so that an upper surface of the pad electrode portion is exposed. A metal film that covers at least a surface that forms the side wall portion of the planarizing layer is disposed in the opening.

### BACKGROUND OF THE INVENTION

### Field of the Invention

The present invention relates to an image pickup device and a display device.

### Description of the Related Art

Improvement in moisture resistance is required in a device, such as a solid state image pickup device, which includes a plurality of layers. Japanese Patent Application Laid-Open No. 2014-060203 discloses a configuration of a solid state image pickup device in which moisture resistance is improved. The solid state image pickup device of Japanese Patent Application Laid-Open No. 2014-060203 includes a substrate in which an opening for an electrode is formed and a plurality of photodiodes are formed on a surface of the substrate. In order to improve moisture resistance at an interlayer boundary exposed from a side wall portion of the opening, a region in which the plurality of photodiodes are formed, the side wall portion of the opening, and a ceiling portion around the opening are covered by a single protective film. A transparent and moisture-resistant material is used as the protective film to thereby improve the moisture resistance of the solid state image pickup device.

Improvement in moisture resistance is also required in a display device which uses an organic light-emitting element disclosed in Japanese Patent Application Laid-Open No. 2012-216495 and a solid state image pickup device which uses an organic photoelectric converting film disclosed in Japanese Patent Application Laid-Open No. 2016-033979.

Patent Literature 1: Japanese Patent Application Laid-Open No. 2014-060203

Patent Literature 2: Japanese Patent Application Laid-Open No. 2012-216495

Patent Literature 3: Japanese Patent Application Laid-Open No. 2016-033979

### SUMMARY OF THE INVENTION

However, when a silicon oxide film, for example, is used as a protective film that covers a side wall portion vertical to the surface of a substrate, it is not possible to completely block entrance of moisture from the side wall portion. This is because water molecules or ions can enter an amorphous structure of the silicon oxide film. In particular, when a material component (for example, a dye-based material) sensitive to moisture is used as a color filter layer used in a solid state image pickup device, the moisture resistance performance of these materials is sometimes insufficient.

Japanese Patent Application Laid-Open No. 2014-060203 discloses a silicon nitride film as a protective film. However, although a silicon nitride film is more effective than a silicon oxide film from a perspective of preventing entrance of moisture from a side wall portion, when the silicon nitride film is stacked on a microlens layer formed in a pixel portion, the silicon nitride film may deteriorate optical characteristics of the solid state image pickup device. Since the deterioration in the optical characteristics results from reflection or refraction of light occurring due to a difference in refractive index between the microlens layer and the silicon nitride film, the deterioration may be structurally inevitable.

The present invention has been made in view of the above-described problems. An object of the present invention is to provide an image pickup device in which moisture resistance is improved without deteriorating optical characteristics.

The present invention provides an image pickup device comprising:

a semiconductor substrate including a pixel region in which pixels are arranged and a pad electrode region on which a pad electrode portion is disposed;

a wiring layer formed on the semiconductor substrate and including the pad electrode portion;

a planarizing layer formed on the wiring layer and formed in a portion upper than the pad electrode portion in the pad electrode region, the planarizing layer including an organic material; and

an inorganic film formed on the planarizing layer, wherein

an opening having a side wall portion is formed in the planarizing layer and the inorganic film so that an upper surface of the pad electrode portion is exposed, and

a metal film that covers at least a surface that forms the side wall portion of the planarizing layer is disposed in the opening.

The present invention also provides an image pickup device comprising:

a semiconductor substrate including a pixel region in which pixels are arranged and a pad electrode region on which a pad electrode portion is disposed; and

a photoelectric converting film formed on the semiconductor substrate and including an organic layer, wherein

an opening having a side wall portion is formed in the organic layer so that an upper surface of the pad electrode portion is exposed, and

a metal film that covers at least a surface that forms the side wall portion of the organic layer is disposed in the opening.

The present invention also provides a display device comprising:

a semiconductor substrate including a pixel region in which pixels are arranged and a pad electrode region on which a pad electrode portion is disposed; and

an organic layer serving as an illuminating layer, formed on the semiconductor substrate, wherein

an opening having a side wall portion is formed in the organic layer so that an upper surface of the pad electrode portion is exposed, and

a metal film that covers at least a surface that forms the side wall portion of the organic layer is disposed in the opening.

According to the present invention, it is possible to provide an image pickup device in which moisture resistance is improved without deteriorating optical characteristics.

Further features of the present invention will become apparent from the following description of exemplary embodiments with reference to the attached drawings.

### BRIEF DESCRIPTION OF THE DRAWINGS

FIG. 1 is a first process diagram illustrating a manufacturing method and a structure of a solid state image pickup device according to Embodiment 1;

FIG. 2 is a second process diagram illustrating a manufacturing method and a structure of a solid state image pickup device according to Embodiment 1;

FIG. 3 is a third process diagram illustrating a manufacturing method and a structure of a solid state image pickup device according to Embodiment 1;

FIG. 4 is a fourth process diagram illustrating a manufacturing method and a structure of a solid state image pickup device according to Embodiment 1;

FIG. 5 is a fifth process diagram illustrating a manufacturing method and a structure of a solid state image pickup device according to Embodiment 1;

FIG. 6 is a diagram illustrating a structure formed by the manufacturing method of the solid state image pickup device according to Embodiment 1;

FIG. 7 is a first process diagram illustrating a manufacturing method and a structure of a solid state image pickup device according to Embodiment 2;

FIG. 8 is a second process diagram illustrating a manufacturing method and a structure of a solid state image pickup device according to Embodiment 2;

FIG. 9 is a third process diagram illustrating a manufacturing method and a structure of a solid state image pickup device according to Embodiment 2;

FIG. 10 is a fourth process diagram illustrating a manufacturing method and a structure of a solid state image pickup device according to Embodiment 2;

FIG. 11 is a diagram illustrating a structure formed by the manufacturing method of the solid state image pickup device according to Embodiment 2;

FIG. 12 is a plan view when the solid state image pickup device according to Embodiment 1 is seen from above;

FIG. 13 is a plan view when the solid state image pickup device according to Embodiment 2 is seen from above;

FIG. 14 is a first process diagram illustrating a manufacturing method and a structure of a solid state image pickup device according to Embodiment 3;

FIG. 15 is a second process diagram illustrating a manufacturing method and a structure of a solid state image pickup device according to Embodiment 3;

FIG. 16 is a third process diagram illustrating a manufacturing method and a structure of a solid state image pickup device according to Embodiment 3;

FIG. 17 is an explanatory diagram of a solid state image pickup device according to Embodiment 4;

FIG. 18 is an explanatory diagram of a display device according to Embodiment 5;

FIG. 19 is an explanatory diagram of a solid state image pickup device according to Embodiment 6;

FIG. 20 is a block diagram illustrating a schematic configuration of an image pickup system according to Embodiment 7; and

FIGS. 21A and 21B are diagrams illustrating a system and a mobile object according to Embodiment 8.

### DESCRIPTION OF THE EMBODIMENTS

Hereinafter, preferred embodiments of the present invention will be described with reference to the drawings. However, the dimensions, materials, shapes, relative positional relationship, and the like of the components described herein may be appropriately changed depending on the structure of the apparatus to which the present invention is applied and various conditions. Therefore, the scope of the present invention is not intended to be limited to the following embodiments.

### Embodiment 1

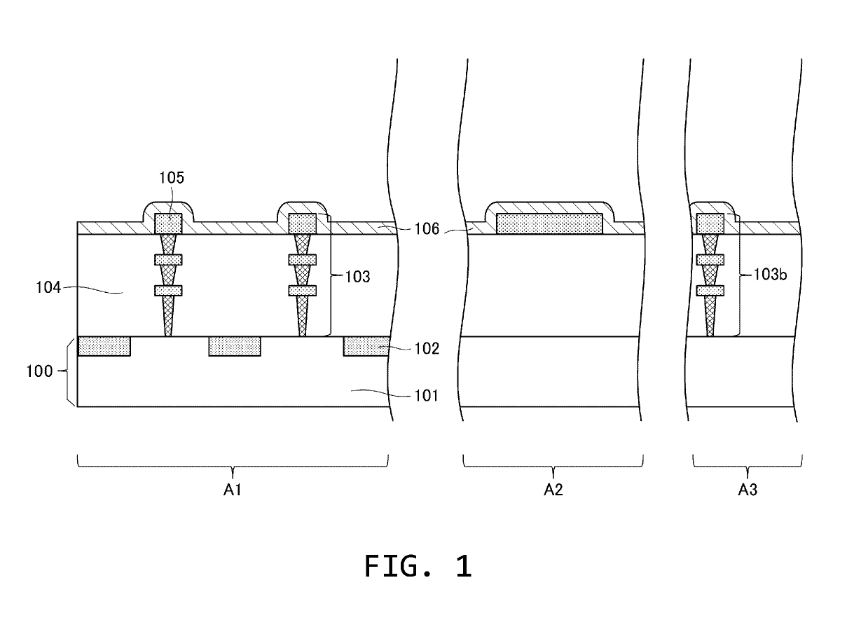

FIGS. 1 to 6 illustrate cross-sectional schematic diagrams of a front-illuminated solid state image pickup device according to the present embodiment in process order. In FIG. 1, a semiconductor substrate 100 includes a first semiconductor region 101 and a second semiconductor region 102. The first semiconductor region 101 is a region shared by a plurality of photoelectric converting portions. The second semiconductor region 102 is configured as a semiconductor region of the opposite conductivity type from the first semiconductor region and forms a PN junction with the first semiconductor region 101. The second semiconductor region 102 is a region in which carriers of the same polarity as signal charges are majority carriers.

Although not illustrated in the drawing, an element separating region is disposed between adjacent second semiconductor regions 102 to electrically separate the second semiconductor regions 102. Insulation film separation such as LOCOS separation or STI separation and PN junction separation (diffusion separation) by a semiconductor region of the opposite conductivity type from the second semiconductor region 102 can be used in the element separating region. Although not illustrated in the drawing, a transfer transistor for transferring charges of the second semiconductor region is also disposed. Hereinafter, the solid state image pickup device will be depicted by dividing into three regions of a pixel region A1, a pad electrode region A2, and “scribing region and effective chip boundary portion” A3.

Reference numeral 103 indicates a wiring layer formed of a metal material or the like. Reference numeral 104 indicates an interlayer insulating film for electrically separating different wiring layers 103. Al, Cu, and the like can be used as a main component of a material that forms wirings of the wiring layer. Moreover, W can be used as a plug for connecting wiring layers. A wiring layer disposed at the farthest position from the semiconductor substrate will be referred to as an uppermost wiring layer 105. A passivation film 106 is formed so as to cover the uppermost wiring layer 105. A plasma nitride film, a plasma oxynitride film, or a laminated film thereof can be used as a material of the passivation film 106. Moreover, a structure called a moisture-resistant ring 103b homogeneous to the wiring layer 103 is disposed in a boundary portion between the scribing region and effective chip boundary portion A3 and an effective chip region. In this way, moisture is prevented from entering an effective chip when a scribe region is diced to assemble a package. The scribing region and effective chip boundary portion A3 is sometimes referred to simply as a scribing region for the sake of convenience.

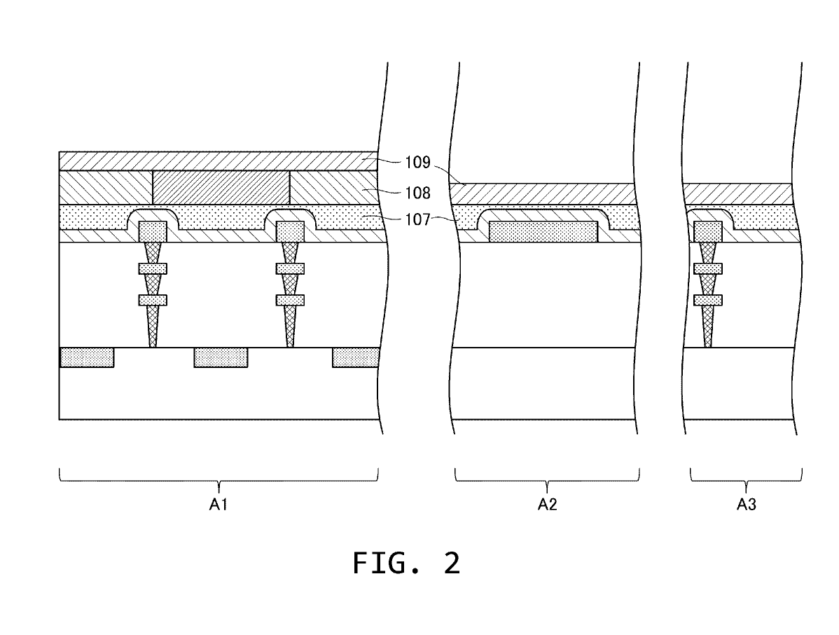

The description will be continued with reference to FIG. 2. First, a first planarizing layer 107 for planarizing the passivation film 106 is formed. In this case, an organic material is applied uniformly on an entire surface using a deposition apparatus.

Subsequently, a color filter layer 108 is patterned so as to be stacked on the first planarizing layer 107 using photolithography. A pattern in which three filters of the three colors of green, blue, and red are arranged in the Bayer arrangement, for example, is used as the color filter layer 108. Pigments, dyes, or hybrid compositions thereof may be used as a color material of the color filter.

Subsequently, a second planarizing layer 109 for planarizing the upper portion of the color filter layer 108 is formed by the same deposition process as the first planarizing layer 107.

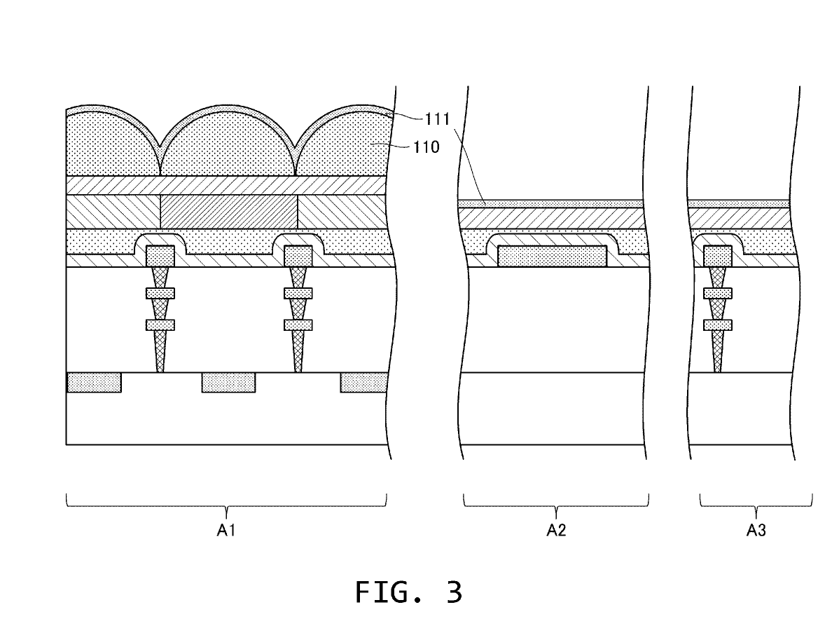

The description will be continued with reference to FIG. 3. First, an on-chip microlens 110 is patterned by photolithography using a gray tone mask, for example.

Subsequently, an inorganic film 111 is formed by plasma CVD. The inorganic film 111 can be selected from a plasma oxide film, a plasma nitride film, a plasma oxynitride film, and the like, for example.

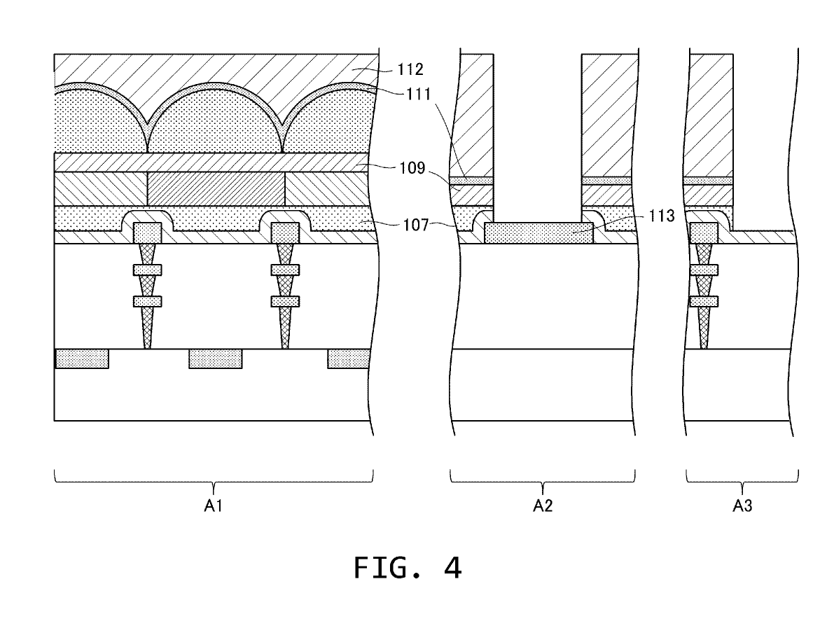

The description will be continued with reference to FIG. 4. In this drawing, the pad electrode portion 113 is open. First, in the pad electrode region A2 and the scribing region and effective chip boundary portion A3, a region other than a region in which the planarizing film (107, 109) formed of an organic material is to be removed is covered by a first photoresist 112. In the deposition process, photolithography-based patterning is used. The pad electrode portion 113 is typically formed of the same metal material as the wiring layer. Therefore, it can be thought that the wiring layer includes the pad electrode portion.

Subsequently, dry etching is performed to remove an organic material. In this case, a mixture gas of O₂ and N₂, for example, is used as a dry etching gas. The first photoresist 112 is removed after the dry etching is performed.

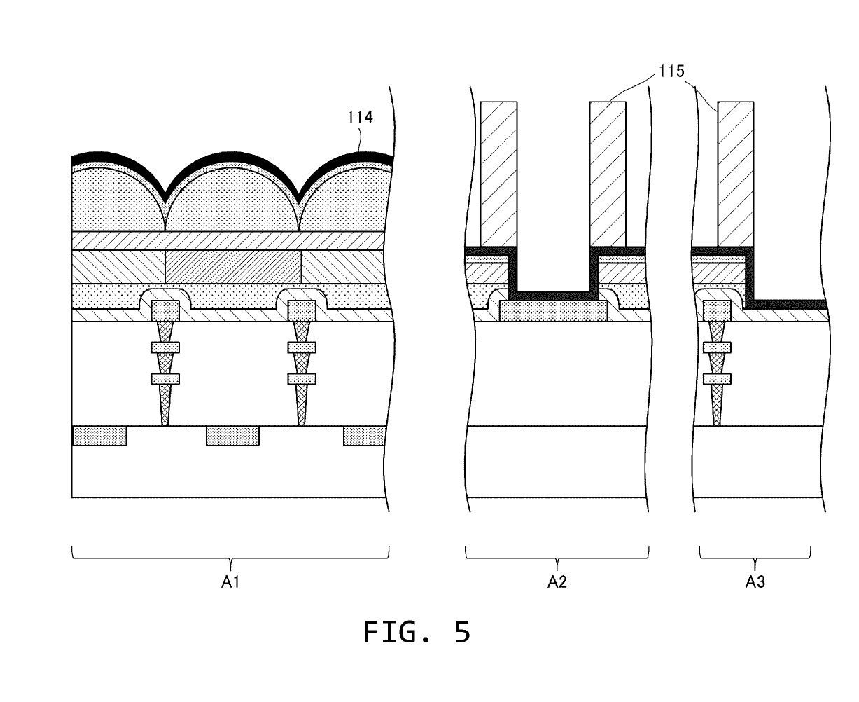

The description will be continued with reference to FIG. 5. First, a process of forming a film (114) that contains metal on an uppermost layer using sputtering will be described. A film that contains metal is a metal film formed of metal or a metal-containing film that includes a material other than metal. Although metal such as Al, Ti, or W, metal-containing materials such as TiN, Al₂O₃, or TaO, and the like are preferably used as the material, there is no limitation thereto, and various materials such as materials made up of metal only, materials in which metal is dispersed in a base material, or materials including metal oxides can be used. In the present specification, although the film is referred to as the “metal film 114” for the sake of convenience, in such a case, it is not intended to exclude a film that includes materials other than metal.

Subsequently, in the pad electrode region A2 and the scribing region and effective chip boundary portion A3, the second photoresist 115 is patterned by photolithography.

Subsequently, dry etching is performed so that the metal film 114 remains on a side wall portion vertical to the substrate and a partial ceiling portion.

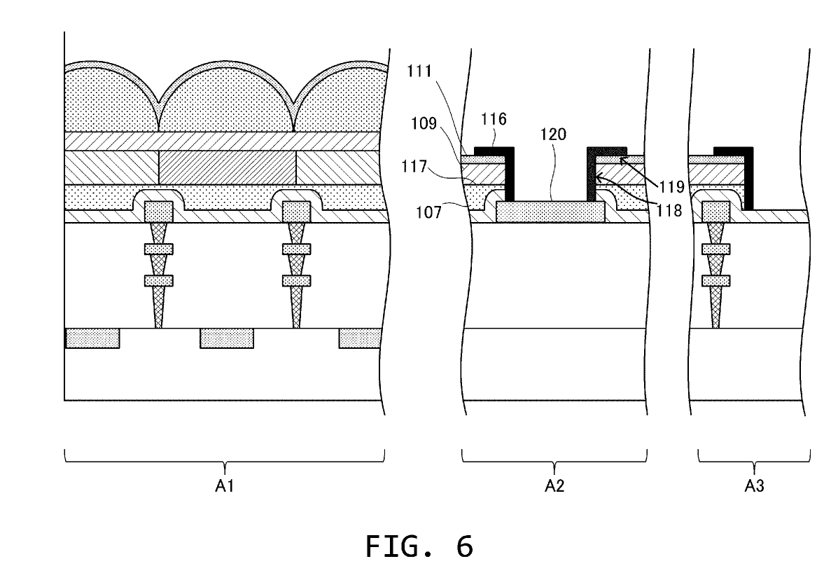

The description will be continued with reference to FIG. 6. A metal film or a metal-containing film on the patterned uppermost surface (an uppermost-surface metal film 116) is illustrated. Similarly to before patterning is performed, the term “uppermost-surface metal film 116” includes either a metal film or a metal-containing film. Moreover, although the terminal “uppermost surface” is used for the sake of convenience, an inorganic film or the like may be formed on the metal film similarly to Embodiments to be described later. The patterned metal film 116 covers the side wall portion 118 and the ceiling portion 119. Here, the side wall portion 118 is a cliff-shaped portion formed by forming such an opening that extends from an uppermost portion of a stacked structure to reach an upper surface of a pad electrode on a substrate so that the upper surface is exposed. An organic material (107, 109) which is a planarizing film is exposed from the side wall portion 118 in a cliff form. Moreover, the inorganic film 111 is also exposed in a cliff form to form a portion of the side wall portion 118.

The ceiling portion 119 is a region extending from an uppermost portion of the side wall portion 118 in a direction parallel to the substrate. In FIG. 6, although an outer edge of the metal film extending to the ceiling portion 119 is not particularly limited, the outer edge is preferably wider to some extent than an edge of an opening of the pad electrode portion or the scribing region portion when seen in a direction of confronting a principal surface of the substrate. In this manner, by arranging the metal film continuously from the uppermost portion of the side wall portion, difficulty in process is reduced as compared to arranging the metal film in the side wall portion only. Moreover, improvement in moisture resistance is also expected.

The metal film may be also formed in the scribing region and effective chip boundary portion A3 as well as the pad electrode region A2. In the embodiments of the present invention, the metal film can be formed in the scribing region and effective chip boundary portion A3 similarly to the pad electrode region A2.

As illustrated in FIG. 6, the metal film is removed completely in the pixel region A1. This is because the metal film interferes entrance of light. Moreover, the metal film is removed completely in a wire bonding portion 120 of the pad electrode region A2. This is to maintain bonding strength between wires such as gold wires and the wire bonding portion 120.

In FIG. 6, in particular, it is important that the boundary portion 117 between the first planarizing layer 107 and the second planarizing layer 109 exposed in a cliff form in the side wall portion 118 is covered by the uppermost-surface metal film 116. If the boundary portion 117 is not covered by a metal film, moisture may enter from the boundary portion 117. As a result, moisture may reach the pixel region Al to reach the color filter layer 108 on the upper layer of the first planarizing layer 107 and the lower layer of the second planarizing layer 109. In this case, the color filter layer 108 may degenerate and spectral transmittance may change. On the other hand, in FIG. 6, at least the surfaces that form the side wall portion, of the respective planarizing layers are covered by a metal film. As a result, it is possible to improve moisture resistance and waterproof properties and to prevent degeneration of the color filter layer 108 due to moisture.

In FIG. 6, the uppermost-surface metal film 116 covers the upper and lower portions of the inorganic film 111 and the upper and lower portions of the passivation film 106 in the cliff-shaped portion that forms the side wall portion 118. In this way, it is possible to further improve the moisture resistance and the waterproof properties. Moreover, the uppermost-surface metal film 116 also covers a predetermined range of regions from the top of the side wall portion 118 within the ceiling portion 119 which is a region parallel to the substrate extending from the uppermost portion of the side wall portion 118. In this manner, since the metal film extending from the side wall portion is also disposed in the direction along the surface of the semiconductor substrate, adhesion between the metal film and the side wall portion is enhanced and the possibility of entrance of moisture is reduced.

Modification

The uppermost-surface metal film 116 may be extended to a peripheral circuit portion (not illustrated) present between the pixel region A1 and the pad electrode region A2. In this way, another advantage that entrance of stray light can be prevented is obtained. When stray light enters the peripheral circuit portion (particularly, transistors), malfunctioning of circuits such as a latch-up circuit may occur. Moreover, when stray light enters the pixel region A1, optical color mixture may also occur. However, when a metal film is disposed on the peripheral circuit, it is possible to reflect stray light and to suppress occurrence of various faults.

According to the present embodiment, the side wall portion that includes an organic material (particularly, a side wall portion of a pad electrode opening and a side wall portion of a scribe opening at a chip end) and a ceiling portion around these side wall portions can be covered by a metal film. As a result, it is possible to suppress entrance of moisture from the outside and to provide a solid state image pickup device having high moisture resistance. When the color filter material is a material that includes dyes, the effect of improvement in moisture resistance increases further. According to the configuration of the modification, it is possible to provide a solid state image pickup device in which entrance of stray light is suppressed.

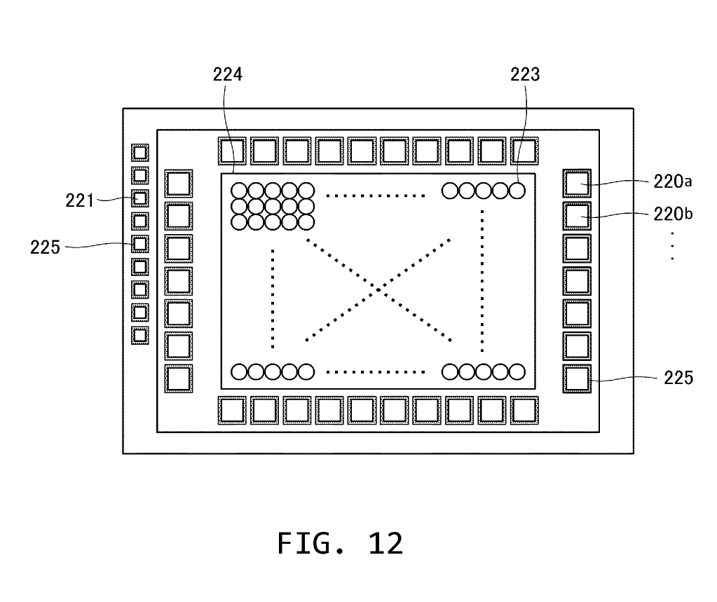

FIG. 12 is a top view when the image pickup device according to the present embodiment is seen from a direction of confronting the principal surface. A plurality of pad electrode portions 220 is disposed around a pixel region portion 224. An opening through which the upper surface of the pad electrode portion is exposed is formed for each pad electrode portion. In the drawing, a TEG pad electrode portion 221 in the scribe region is also depicted.

The uppermost-surface metal film is disposed so as to cover an organic material in at least the side wall portion of each opening. In the drawing, although the metal film is also disposed in a portion of the ceiling portion, the metal film in the ceiling portion is not essential, and the metal film is separated between the openings. In other words, the uppermost-surface metal film 225 covers the individual electrodes included in the pad electrode portion 220 and individual electrodes included in the TEG pad electrode portion 221 in the scribe region. Here, the first pad electrode portion is referred to as 220a, the second pad electrode portion is referred to as 220b, a metal film disposed in a side wall portion of an opening corresponding to the first pad electrode portion 220a is referred to as a first section, and a metal film disposed in a side wall portion of an opening corresponding to the second pad electrode portion 220b is referred to as a second section. In this case, the first section and the second section are electrically insulated.

With such a configuration, electrical short does not occur easily in the pad electrode portion 220 and the TEG pad electrode portion 221 in the scribe region. In the present embodiment, similarly to the embodiments to be described later, an insulating inorganic film may be disposed between an electrode portion and a metal film to further enhance insulating properties.

### Embodiment 2

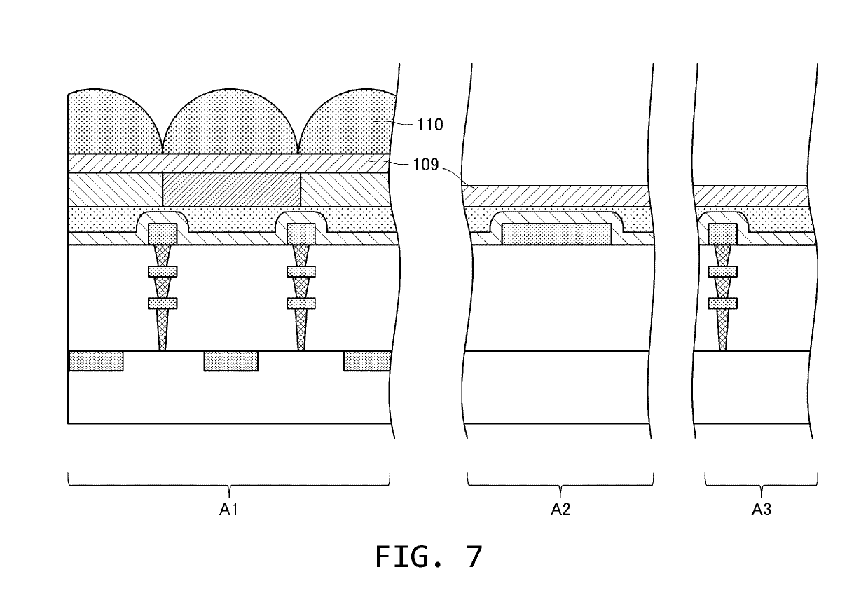

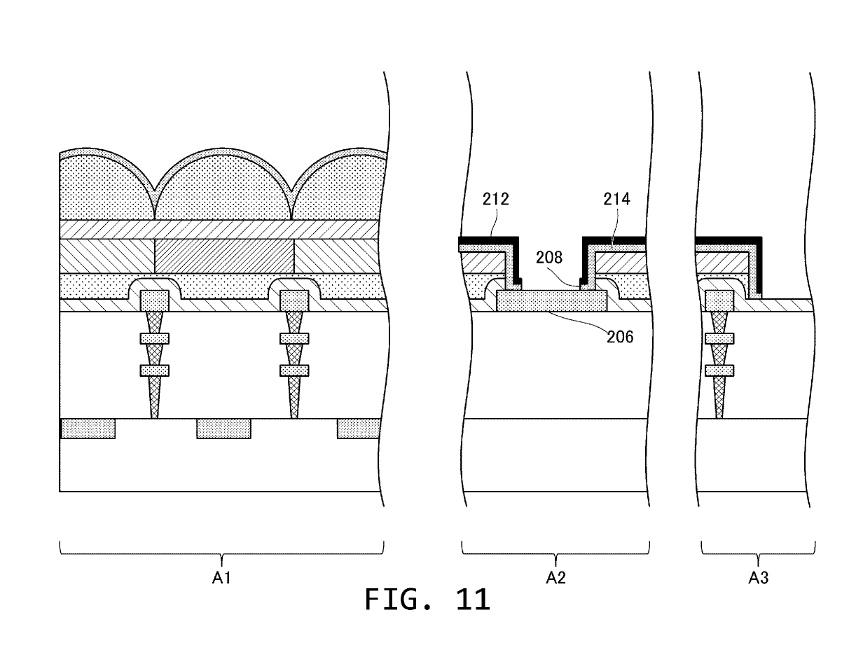

Hereinafter, Embodiment 2 will be described focusing on the difference from Embodiment 1. FIGS. 7 to 11 illustrate a manufacturing method of a solid state image pickup device according to the present embodiment. As illustrated in FIG. 11, a solid state image pickup device of the present embodiment is different from that of Embodiment 1 in that the uppermost-surface metal film 212 continuously covers the pad electrode region A2 and the scribing region and effective chip boundary portion A3. Moreover, an inorganic film 208 side wall portion is disposed between the uppermost-surface metal film 212 and the side wall portion or the ceiling portion. In this way, a two-layer structure of an inorganic insulating film and a metal film is formed.

The description will be continued with reference to FIG. 7. The manufacturing method of Embodiment 2 up to the process of forming the on-chip microlens 110 is the same as that of Embodiment 1.

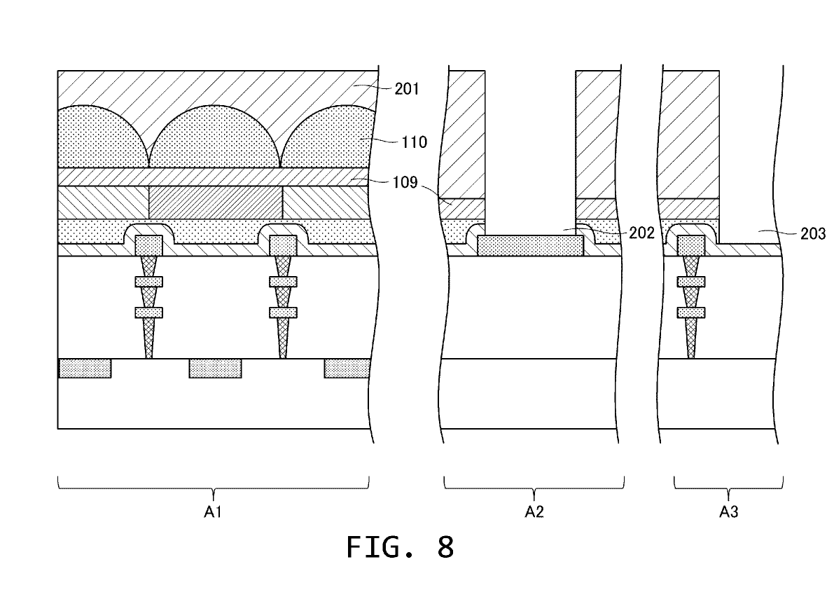

Subsequently, in Embodiment 1, the inorganic film 111 is formed as illustrated in FIG. 3. On the other hand, as illustrated in FIG. 8, in the present embodiment, a photoresist 201 is formed. A third photoresist 201 is patterned in order to etch an organic film on an opening 202 in the pad electrode region A2 and an opening 203 in the scribing region and effective chip boundary portion A3. Dry etching is performed after the patterning is performed. After that, the third photoresist 201 is removed. The term “third photoresist” is used for distinguishing from other photoresists common to Embodiment 1 and is not associated with the order of using photoresists.

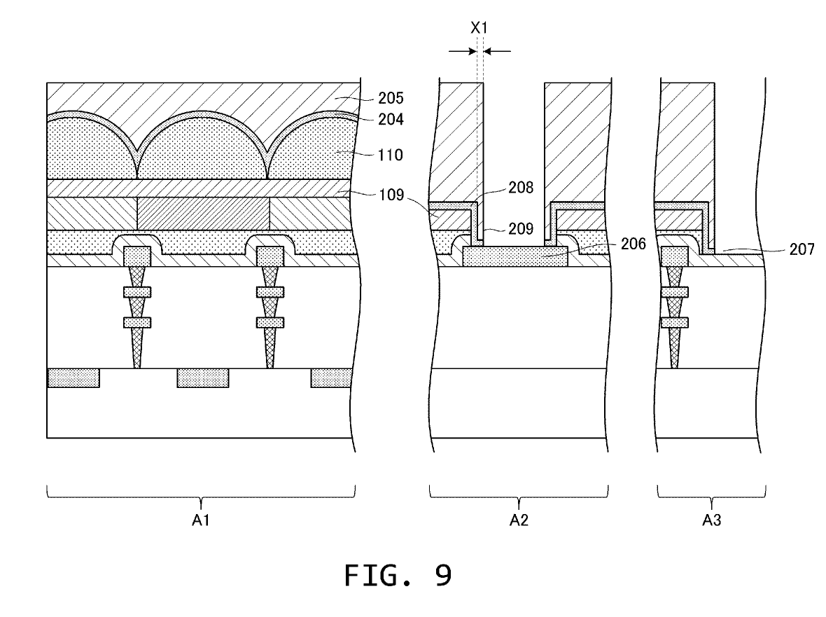

The description will be continued with reference to FIG. 9. In this drawing, an inorganic film is formed in a side wall portion vertical to the substrate and a portion of the ceiling portion. After the third photoresist 201 is removed from the state of FIG. 8, an inorganic film 204 is formed by plasma CVD. In this way, an inorganic film is formed on the on-chip microlens 110. Moreover, in the pad electrode region A2, an inorganic film is formed on an upper surface of the second planarizing film 109 and the side wall portion and the bottom portion of the opening 202. The inorganic film formed on the side wall portion will be referred to as an inorganic film side wall portion 208. Moreover, in the scribing region and effective chip boundary portion A3, an inorganic film is formed on the upper surface of the second planarizing film and the side wall portion and the bottom portion of the opening.

Subsequently, as illustrated in FIG. 9, a first photoresist 205 is patterned. This corresponds to the first photoresist 112 of Embodiment 1. A pad electrode portion 206 in the pad electrode region A2 and an opening 207 in the scribing region and effective chip boundary portion A3 are open by photolithography to etch the inorganic film. In this case, the inorganic film can be selected from a plasma oxide film, an oxynitride film, a nitride film, and the like. In each opening, an end of the first photoresist 205 is preferably at a position 209 that protrudes further from an inorganic film side wall portion 208 formed in an organic film side wall portion. For example, when a metal film formed in a subsequent process has a thickness of 100 nm, an offset X1 in FIG. 9 is preferably 100 nm or more. By doing so, the metal film is insulated by the inorganic film 204, and electrical short with pad electrodes can be prevented.

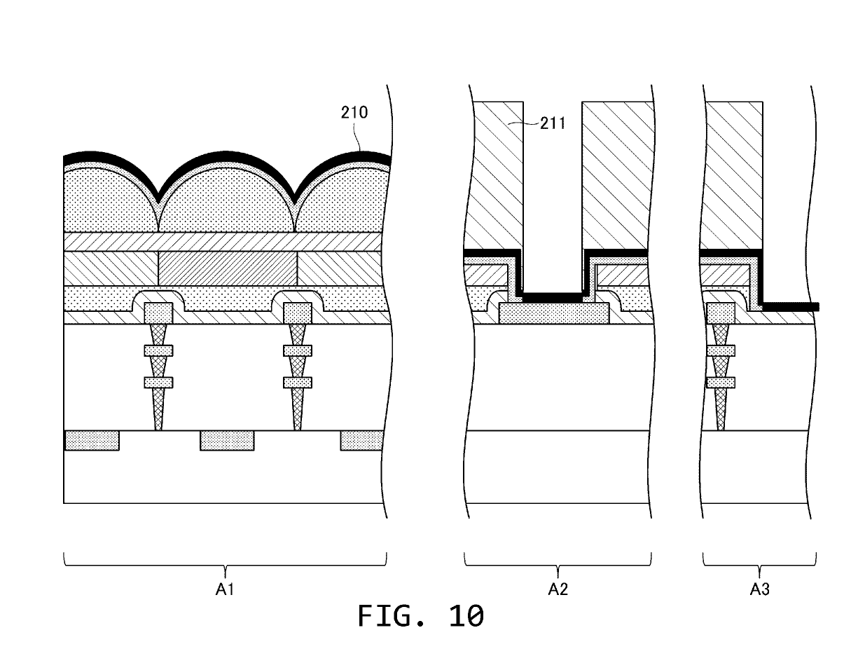

The description will be continued with reference to FIG. 10. First, the metal film 210 is formed by sputtering. When the metal film is patterned, an uppermost-surface metal film 212 is finally obtained. A material of the metal film can be selected from various metals or metal-containing materials similarly to Embodiment 1.

Subsequently, in the pad electrode region A2 and the scribing region and effective chip boundary portion A3, the second photoresist 211 is patterned by photolithography in order to etch the metal film while leaving the side wall portion of the opening and a partial ceiling portion.

The description will be continued with reference to FIG. 11. Dry etching is performed after such patterning as illustrated in FIG. 10 is performed, and the second photoresist 211 is removed, whereby the patterned uppermost surface metal film or the patterned metal-containing film (the uppermost-surface metal film 212) is formed as illustrated in FIG. 11.

In FIG. 11, the uppermost-surface metal portion 212 covers an interlayer boundary (particularly, an organic material exposed in a cliff form) of the side wall portion 213 of the opening. The uppermost-surface metal portion 212 also covers the ceiling portion 214 of a layer structure including an organic material. In this way, a solid state image pickup device in which entrance of moisture is prevented and which has high moisture resistance and waterproof properties is provided. In FIG. 11, a portion of the inorganic film side wall portion 208 is disposed between the uppermost-surface metal film 212 and the pad electrode portion 206. Due to this, insulation is maintained. Moreover, since dual films including a metal film and an inorganic film are formed in the side wall portion, the effect of preventing entrance of moisture from the outside is enhanced as compared to forming the metal film only and moisture resistance is improved.

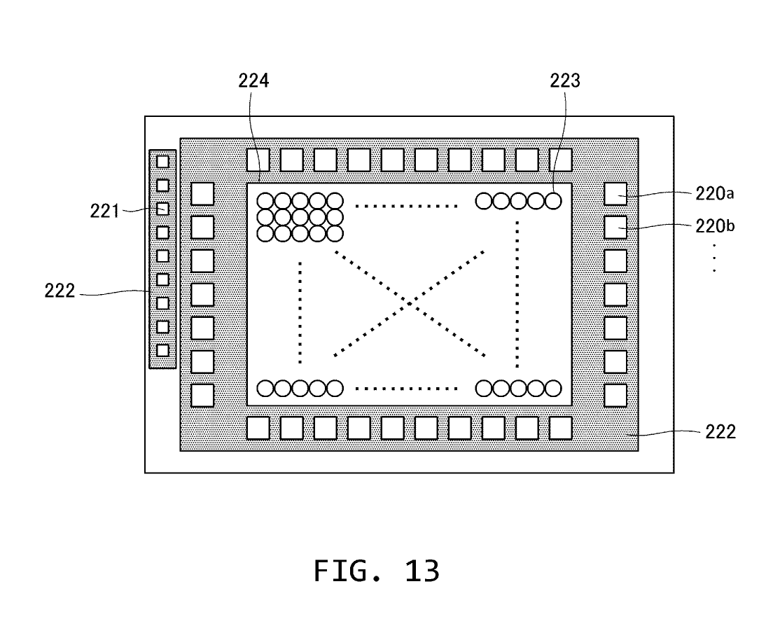

FIG. 13 is a top view when the substrate according to Embodiment 2 is seen from the direction of confronting the principal surface. A plurality of pad electrode portions 220 is disposed around the pixel region portion 224. An opening through which the upper surface of the pad electrode portion is exposed is formed for each pad electrode portion, similarly to FIG. 12. In the drawing, a TEG pad electrode portion 221 in the scribe region is also depicted.

An uppermost-surface metal film 222 is provided so as to cover the pad electrode portion 220 and the TEG pad electrode portion 221 in the scribe region. The uppermost-surface metal film 222 in the drawing includes a section that electrically connects metal films that cover an organic material in the side wall portion of each opening and cover a side wall portion of each opening. Here, the first pad electrode portion is referred to as 220a, the second pad electrode portion is referred to as 220b, a metal film disposed in a side wall portion of an opening corresponding to the first pad electrode portion 220a is referred to as a first section, and a metal film disposed in a side wall portion of an opening corresponding to the second pad electrode portion 220b is referred to as a second section. In this case, the uppermost-surface metal film includes a section that electrically connects the first section and the second section. However, since an insulating film is disposed between the first section (the uppermost-surface metal film) and the pad electrode portion and between the second section and the pad electrode portion, the respective pad electrodes are not electrically connected. For the sake of convenience, it is described that the uppermost-surface metal film 222 includes a plurality of sections. However, actually, a metal material that forms the uppermost-surface metal film 222 is continuously disposed from a side wall portion of the opening corresponding to the first pad electrode portion 220a to a side wall portion of the opening corresponding to the second pad electrode portion 220b whereby the respective sections are formed.

As illustrated in the drawing, although the on-chip microlens 223 is disposed in an array form in the pixel region portion 224, the metal film is not disposed in this section. The offset X1 illustrated in FIG. 9 needs to be set to an appropriate value so that electrical short does not occur between electrode pads. It is preferable to secure the length of an insulating inorganic film that protrudes upward from the pad electrode portion 206.

### Embodiment 3

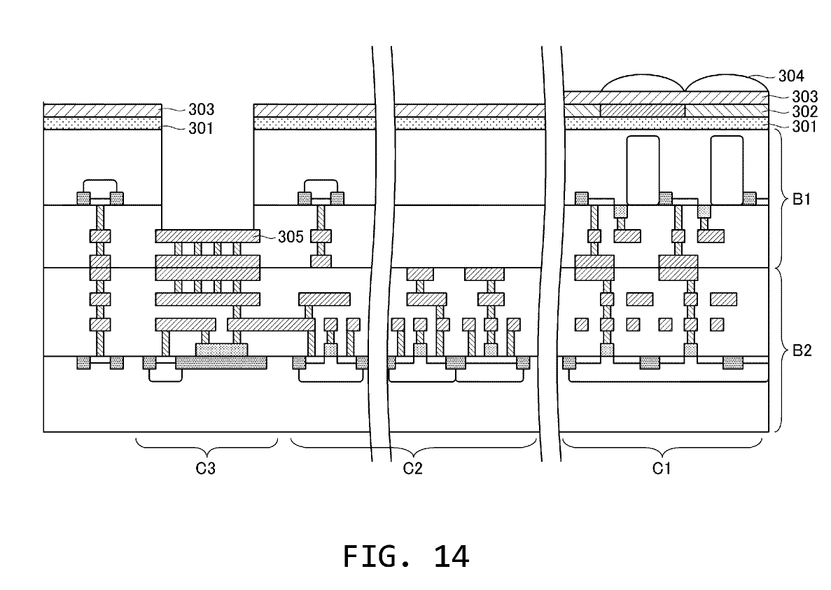

In the present embodiment, a so-called back-illuminated solid state image pickup device is presented as a solid state image pickup device. The solid state image pickup device illustrated in FIG. 14 includes a first semiconductor substrate B1 in which a first transistor and a photoelectric converting element are disposed and a second semiconductor substrate B2 in which a second transistor is disposed. A surface on which the first transistor of the first semiconductor substrate B1 is disposed and a surface on which the second transistor of the second semiconductor substrate B2 is disposed are disposed to face each other. The solid state image pickup device of FIG. 14 is divided into a pixel region C1, a driving circuit region C2, and an electrode pad region C3.

A first planarizing layer 301 formed of an organic material, a color filter layer 302, a second planarizing layer 303, and an on-chip microlens layer 304 are stacked on the semiconductor substrate. The color filter layer and the on-chip microlens layer are formed in the pixel region C1.

Subsequently, resist patterning and dry etching are performed by photolithography in order to open an electrode pad 305 of the electrode pad region C3.

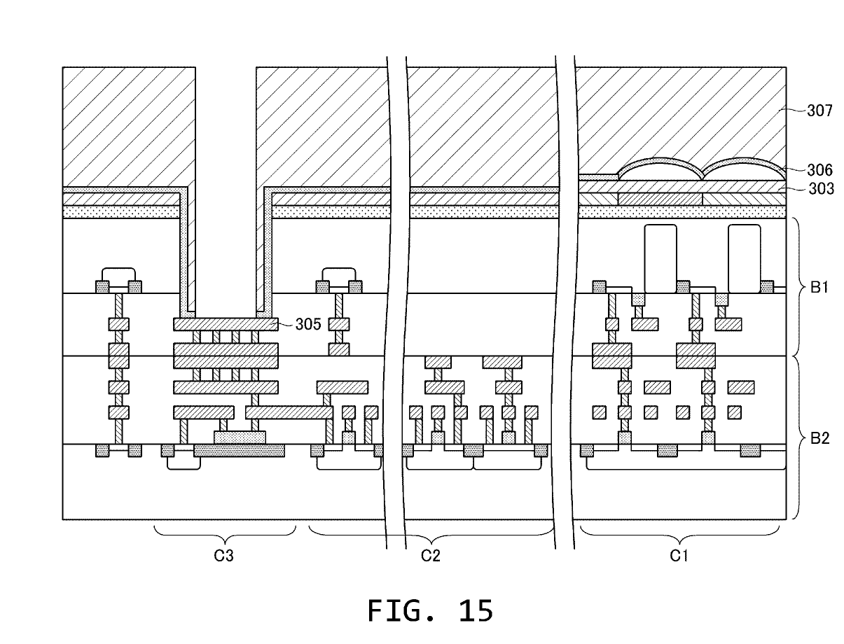

The description will be continued with reference to FIG. 15. An inorganic film 306 is formed by plasma CVD on the on-chip microlens layer 304 in the pixel region C1 and the second planarizing layer 303 in the other regions.

Subsequently, a photoresist 307 for removing only an inorganic film on the electrode pad 305 of the electrode pad region C3 is formed. A portion on the electrode pad 305 of the electrode pad region C3 is open by photolithography and dry etching. In this case, dry etching is preferably performed using CF₄/O₂/Ar-based gas. Moreover, a material of the inorganic film 306 can be selected from a silicon oxide film, a silicon oxynitride film, a silicon nitride film, and the like.

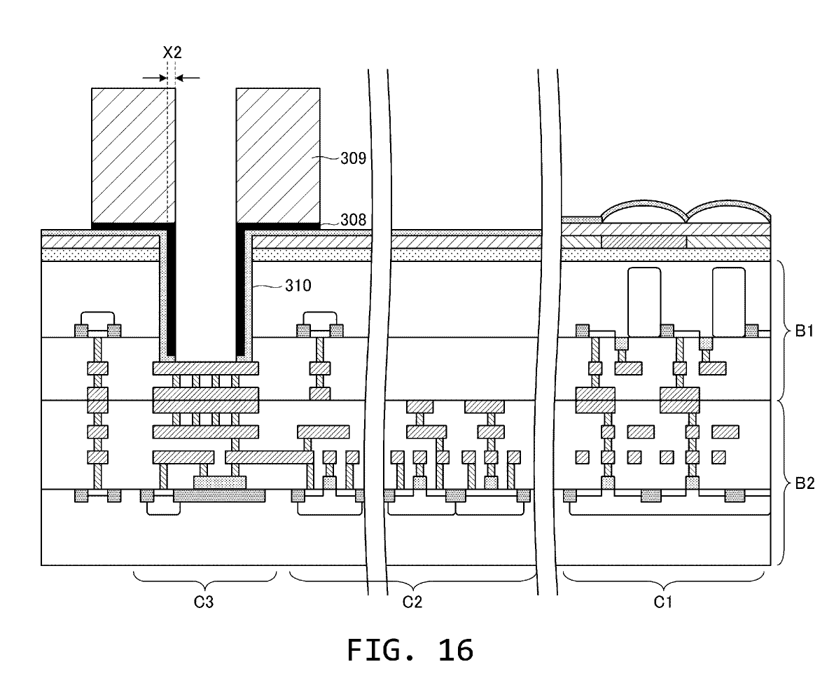

The description will be continued with reference to FIG. 16. A metal film 308 is further formed on the inorganic film 306 by sputtering or the like. Patterning is performed using a photoresist 309, and the surface of the electrode pad 305 of the electrode pad region C3 is open by dry etching. In this way, the metal film 308 is formed on the side wall portion vertical to the substrate and a partial ceiling portion.

In this case, similarly to Embodiment 2, it is preferable to adjust an offset X2 for adjusting the extension distance of the inorganic film 306 in order to secure insulation performance of the inorganic film 306. For example, when the metal film 308 has a thickness of 100 nm, the offset X2 is preferably 100 nm or more. In this way, electrical short between the pad electrode and the metal film can be prevented. Moreover, since it is preferable that a parasitic diode structure is not formed in a substrate exposure portion 310 positioned in a side wall of the electrode pad region C3 of the first semiconductor substrate B1, it is not necessary to form an inorganic film and the configuration for preventing the electrical short.

According to the present embodiment, it is possible to provide a back-illuminated solid state image pickup device in which entrance of moisture is prevented and in which moisture resistance and waterproof properties are improved. As illustrated in FIG. 14, a vertical portion of the opening of the present embodiment reaches the first semiconductor substrate B1 formed of silicon or the like without remaining in the planarizing layer formed of an organic material. However, since the wall portion and the ceiling portion near the opening are covered by the metal film 308 as illustrated in FIG. 16, it is possible to secure moisture resistance. In this case, an inorganic layer is disposed between the silicon or the like and the metal film whereby insulating properties are also secured.

### Embodiment 4

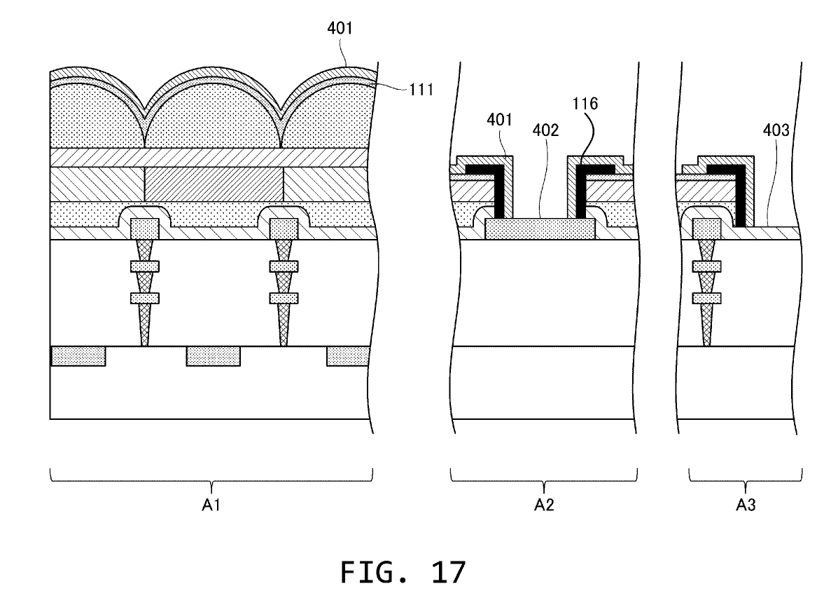

In the present embodiment, another process is added to the solid state image pickup device of Embodiment 1. In FIG. 17, a second inorganic film 401 is formed by plasma CVD as a subsequent process of FIG. 6 illustrated in Embodiment 1. Subsequently, a pad electrode portion 402 of the pad electrode region A2 and an opening 403 of the scribing region and effective chip boundary portion A4 are open by photolithography and dry etching.

According to the present embodiment, since the uppermost-surface metal film 116 is covered by the second inorganic film 401, corrosion and oxidation of metal can be prevented. Moreover, a dual-inorganic-film structure made up of the inorganic film 111 and the second inorganic film 401 is formed on the on-chip microlens of the pixel region A1. Here, by selecting an optimal refractive index that maximizes an anti-reflection effect, improvement in light utilization efficiency is also obtained. There is no change in a moisture resistance improvement effect regardless whether the two types of inorganic films have different refractive index or the same refractive index.

According to the present embodiment, since an inorganic insulating film is formed in an exposure portion of the metal film of Embodiment 1 as a second inorganic film, moisture resistance of the solid state image pickup device is improved. Furthermore, improvement in light utilization efficiency and an effect of preventing corrosion of metal surface or oxidation are obtained.

### Embodiment 5

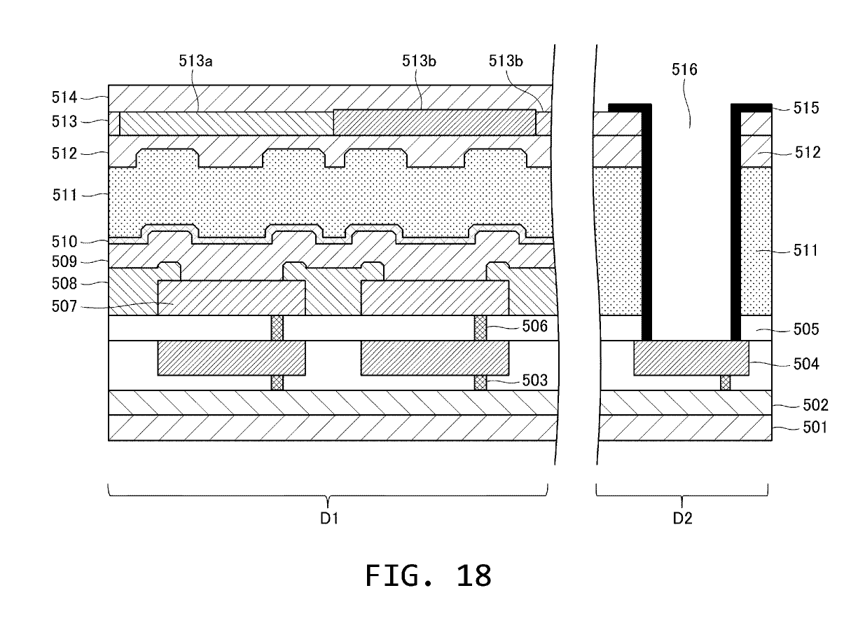

The present embodiment aims to improve moisture resistance of a display device which uses an organic light-emitting element. FIG. 18 illustrates a cross-sectional structure of a display device, which is divided into a pixel region D1 and a pad electrode region D2.

A manufacturing method or the like of the organic light-emitting element is disclosed in Japanese Patent Application Laid-Open No. 2012-216495. Briefly, a driving circuit layer 502 is formed on a substrate 501, and a first connection hole 503, a first electrode 504, a first planarizing layer 505, a second connection hole 506, and a second electrode 507 are formed successively. After an insulating layer 508 is formed, the insulating layer 508 is patterned so that the second electrode 507 and an organic layer 509 make contact with each other. In this way, an anode electrode for the organic layer 509 is formed. Moreover, a third electrode 510 is positioned on an upper layer of the organic layer 509 to function as a cathode electrode. The organic layer 509 functions as an illuminating layer.

Subsequently, a first protective layer 511, a second planarizing layer 512, a color filter layer 513 including color filters of three colors of a green filter 513a, a red filter 513b, and a blue filter 513c, and a second protective layer 514 are stacked successively. The first protective layer 511 mainly uses a plasma nitride film and the second planarizing layer 512, the color filter layer 513, and the second protective layer 514 which are upper layers of the first protective layer 511 use an organic material.

Subsequently, patterning for opening a pad electrode is performed using photolithography and dry etching. In order to prevent deterioration of the organic layer 509, all treatments after forming the organic layer 509 are performed at 110° C. or lower.

In the present embodiment, a patterned metal film is formed in the side wall portion and the ceiling portion of the pad electrode opening 516 illustrated in FIG. 18.

In this manner, the patterned metal film 515 formed by the present embodiment can block entrance of moisture from an interlayer boundary and prevent deterioration of an organic film (particularly, the color filter layer). As a result, an effect of improving moisture resistance and waterproof properties of the display device including an organic light-emitting element is obtained.

### Embodiment 6

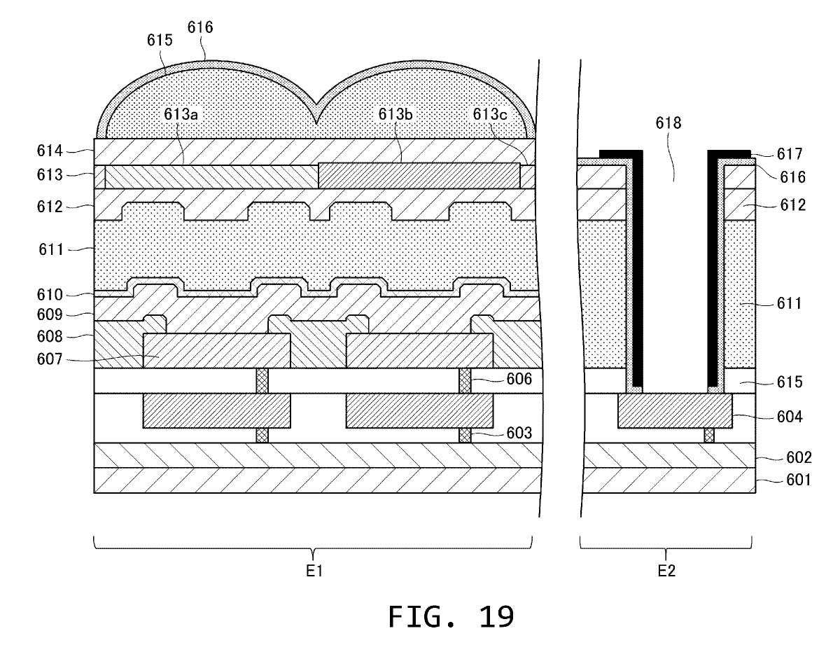

The present embodiment aims to improve moisture resistance in a solid state image pickup device which uses an organic photoelectric converting film including an organic layer serving as a photoelectric converting film. FIG. 19 illustrates a cross-sectional structure of a solid state image pickup device, which is divided into a pixel region E1 and a pad electrode region E2.

A detailed model information or the like of the solid state image pickup device is disclosed in Japanese Patent Application Laid-Open No. 2016-033979. Briefly, a pixel circuit layer 602 is formed on a substrate 601, and a first connection hole 603, a first electrode 604, a first planarizing layer 605, a second connection hole 606, and a pixel electrode 607 are formed successively. After an insulating layer 608 is formed, the insulating layer 608 is patterned so that the pixel electrode 607 and an organic photoelectric converting film 609 make contact with each other. Moreover, an opposing electrode 610 is positioned on an upper layer of the organic photoelectric converting film 609 and is used as a ground electrode when resetting carriers in the organic photoelectric converting film.

Subsequently, a dielectric film 611, a second planarizing layer 612, a color filter layer including color filters of three colors of a green filter 613a, a red filter 613b, and a blue filter 613c, and a third planarizing layer 614 are stacked successively. The dielectric film 611 can be selected from a nitride film, an oxynitride film, an oxide film, and the like. The second planarizing layer 612, the color filter layer 613, and the third planarizing layer 614 which are upper layers of the dielectric film 611 use an organic material.

Subsequently, after an on-chip microlens 615 is patterned, a pad electrode portion opening 618 is open by photolithography and dry etching. An inorganic film 616 is formed on an uppermost surface including the pad electrode portion opening 618 by plasma CVD. The inorganic film 616 can be selected from an oxide film, a nitride film, and the like.

Subsequently, after removing a portion of an inorganic film at the bottom portion of the pad electrode portion opening 618 by photolithography and dry etching, a metal film is formed. Photolithography and dry etching are performed so that the metal film remains in the side wall portion and a partial ceiling portion of the pad electrode portion opening 618.

By the above-described processes, a patterned metal film 617 is formed. The metal film 617 suppresses entrance of moisture from an interlayer boundary portion. Due to the presence of the inorganic film 616, improvement in an insulation effect and further improvement in moisture resistance can be expected. As a result, moisture resistance and waterproof properties of the solid state image pickup device that includes an organic photoelectric converting film are improved.

As described above, according to the embodiments of the present invention, a portion in which an end of an organic material is exposed in a ground layer form in a cliff is covered by a metal film. As a result, since entrance of moisture from the outside is blocked, deterioration of an organic material particularly can be prevented. In general, metal crystals formed by metallic bonds are known to have the closest-packed structure. For example, the minimum distance between adjacent atoms for AL in a room temperature is approximately 2.86 Å whereas the distance is approximately 3.0 Å for water molecules, and therefore, the water molecules cannot pass through the gap between crystal lattices. Due to this, by using the present invention, it is possible to manufacture an electronic device having improved moisture resistance.

### Embodiment 7

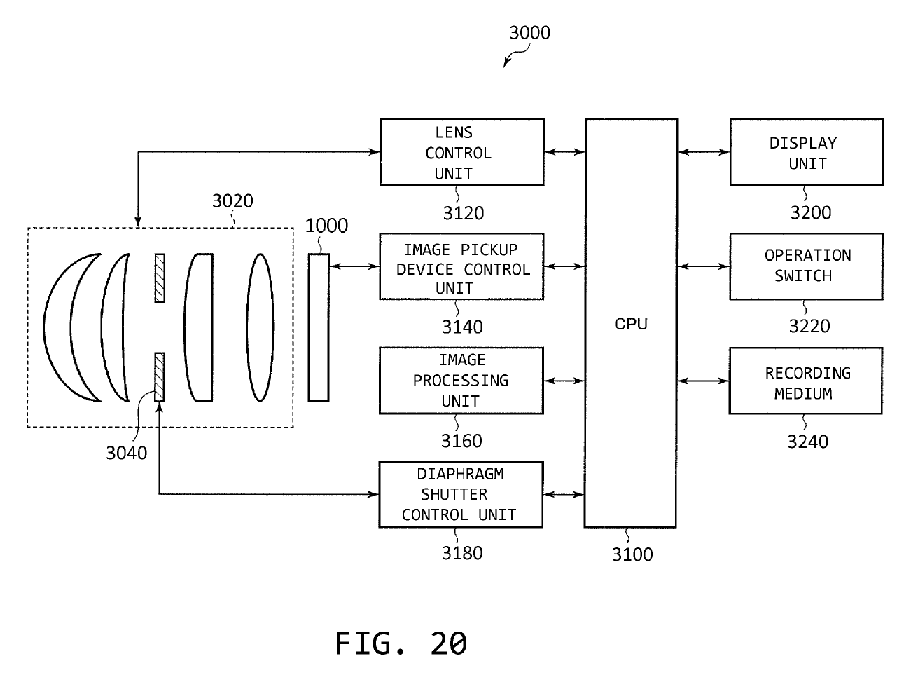

An image pickup system according to Embodiment 7 of the present invention will be described with reference to FIG. 20. FIG. 20 is a block diagram illustrating a schematic configuration of an image pickup system according to the present embodiment.

The solid state image pickup devices (hereinafter collectively referred to as an image pickup device 1000) described in the respective embodiments can be applied to various image pickup systems. An applicable image pickup system is not particularly limited, and examples thereof include a digital still camera, a digital camcorder, a surveillance camera, a copying machine, a facsimile, a cellular phone, an in-vehicle camera, and an observation satellite. Moreover, a camera module including an optical system such as a lens and an image pickup device is also included in the image pickup system. FIG. 20 illustrates a block diagram of a digital still camera as an example of theses image pickup systems.

An image pickup system 3000 includes an image pickup optical system 3020, a CPU 3100, a lens control unit 3120, an image pickup device control unit 3140, an image processing unit 3160, a diaphragm shutter control unit 3180, a display unit 3200, an operation switch 3220, and a recording medium 3240.

The image pickup optical system 3020 is an optical system for forming an optical image of a subject and includes a lens group, a diaphragm 3040, and the like. The diaphragm 3040 includes a function of adjusting a light quantity during photographing by adjusting an opening diameter thereof and a function of an exposure adjustment shutter during photographing of still images. The lens group and the diaphragm 3040 are held to advance and retract in an optical axis direction and realize a magnification changing function (a zooming function) and a focusing adjustment function with the interlocked operation. The image pickup optical system 3020 may be integrated with the image pickup system and may be an image pickup lens that can be attached to the image pickup system.

The image pickup device 1000 is disposed in an image space of the image pickup optical system 3020 so that an imaging plane is positioned therein. The image pickup device 1000 is the solid state image pickup device described in the embodiment and is configured to include a CMOS sensor (a pixel region) and a peripheral circuit (a peripheral circuit region) thereof. The image pickup device 1000 forms a two-dimensional single-panel color sensor such that pixels having a plurality of photoelectric converting portions are arranged two-dimensionally and color filters are disposed in these pixels. The image pickup device 1000 photoelectrically converts a subject image picked up by the image pickup optical system 3020 and outputs the subject image as an image signal or a focus detection signal.

The lens control unit 3120 has a function of controlling movement of the lens group of the image pickup optical system 3020 to change a magnification and adjust a focal point and is configured as a circuit or a processing device configured to realize the function. The diaphragm shutter control unit 3180 has a function of adjusting an imaging light quantity by changing an opening diameter of the diaphragm 3040 (by varying an f-number) and is configured as a circuit or a processing device configured to realize the function.

The CPU 3100 is a control device in a camera that controls various operations of a camera body and includes an arithmetic unit, a ROM, a RAM, an A/D converter, a D/A converter, a communication interface circuit, and the like. The CPU 3100 controls operations of various units in the camera according to a computer program stored in a ROM or the like to execute a series of photographing operations such as AF, imaging, image processing, and recording including focusing state detection (focal point detection) of the image pickup optical system 3020. The CPU 3100 is also a signal processing unit.

The image pickup device control unit 3140 has functions of controlling an operation of the image pickup device 1000 and A/D converting signals output from the image pickup device 1000 to output the same to the CPU 3100 and is configured as a circuit or a control device configured to realize the functions. The A/D conversion function may be included in the image pickup device 1000. The image processing unit 3160 has a function of performing image processing such as γ-conversion or color interpolation with respect to the A/D-converted signals to generate image signals and is configured as a circuit or a control device configured to realize the function. The display unit 3200 is a display device such as a liquid crystal display device (LCD) and displays information on a camera photographing mode, a preview image before photographing, a confirmation image after photographing, a focusing state during focal point detection, and the like. The operation switch 3220 includes a power switch, a release (photographing trigger) switch, a zoom switch, a photographing mode selection switch, and the like. The recording medium 3240 records photographed images and the like and may be included in the image pickup system and may be detachably attached to the image pickup system like a memory card.

In this manner, by forming the image pickup system 3000 to which the image pickup devices 1000 of the respective embodiments, it is possible to realize a high-performance image pickup system capable of adjusting a focal point with high accuracy and acquiring images with a high depth of field.

### Embodiment 8

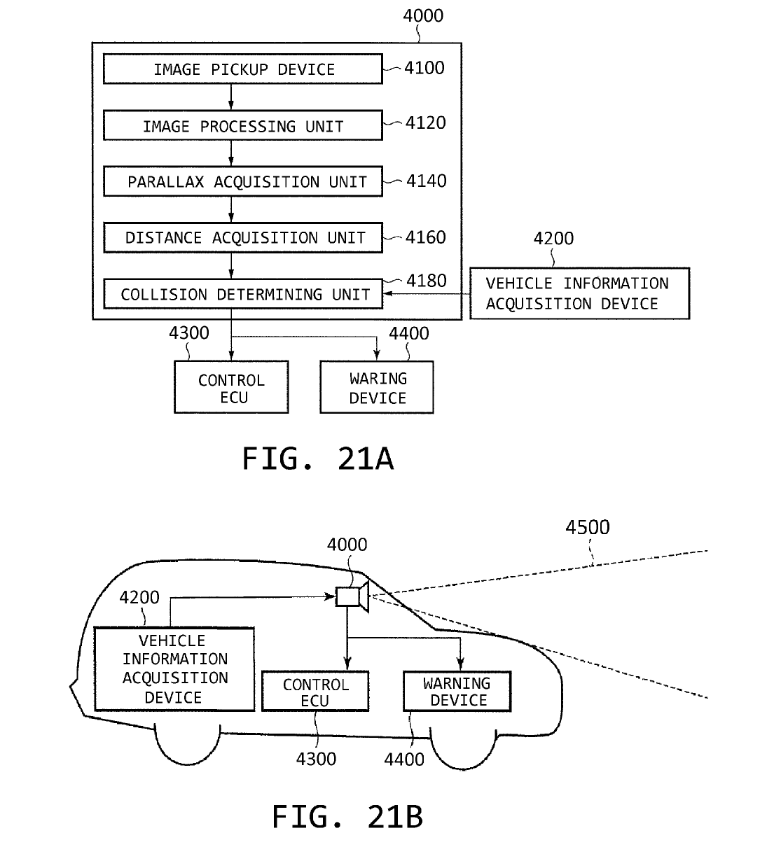

An image pickup system and a mobile object according to Embodiment 8 of the present invention will be described with reference to FIGS. 21A and 21B. FIGS. 21A and 21B are diagrams illustrating a configuration of an image pickup system and a mobile object according to the present embodiment.

FIG. 21A illustrates an example of an image pickup system 4000 of an in-vehicle camera. The image pickup system 4000 includes an image pickup device 4100. The image pickup device 4100 is any one of the solid state image pickup devices described in the respective embodiments. The image pickup system 4000 includes an image processing unit 4120 that performs image processing with respect to a plurality of pieces of image data acquired by the image pickup device 4100 and a parallax acquisition unit 4140 that calculates a parallax (a phase difference of parallax images) from the plurality of pieces of image data acquired by the image pickup device 4100. The image pickup system 4000 also includes a distance acquisition unit 4160 that calculates a distance to an object on the basis of the calculated parallax and a collision determining unit 4180 that determines the possibility of collision on the basis of the calculated distance. Here, the parallax acquisition unit 4140 and the distance acquisition unit 4160 is an example of distance information acquisition means that acquires distance information to an object. That is, the distance information is information on a parallax, a defocus amount, and a distance or the like to an object. The collision determining unit 4180 may determine the possibility of collision using any one of these pieces of distance information. The distance information acquisition means may be realized as dedicated hardware and may be realized as a software module. Moreover, the distance information acquisition means may be realized as a field programmable gate array (FPGA), an application specific integrated circuit (ASIC), or the like and may be realized as a combination thereof.

The image pickup system 4000 is connected to a vehicle information acquisition device 4200 and can acquire vehicle information such as a vehicle speed, a yaw rate, and a steering angle. Moreover, the image pickup system 4000 is connected to a control ECU 4300 which is a control device that outputs a control signal for generating a braking force with respect to a vehicle on the basis of a determination result obtained by the collision determining unit 4180. That is, the control ECU 4300 is mobile object control means that controls a mobile object on the basis of distance information. Moreover, the image pickup system 4000 is also connected to an a warning device 440 that issues a warning to a driver on the basis of a determination result obtained by the collision determining unit 4180. For example, when the collision determining unit 4180 determines that the possibility of collision is high, the control ECU 4300 performs vehicle control to avoid collision to alleviate injury by applying the brake, removing the force applied to an accelerator pedal, and suppressing engine output. The warning device 4400 warns users by issuing warning such as sound, displaying warning information on a screen of a navigation system or the like, or vibrating a seat belt or a steering wheel.

In the present embodiment, the surroundings of a vehicle (for example, front or rear sides) are photographed by the image pickup system 4000. FIG. 21B illustrates the image pickup system 4000 when the front-side view of a vehicle (an imaging range 4500) is photographed. A vehicle information acquisition device 4200 outputs instructions so that the image pickup system 4000 is operated to execute a photographing operation. By using the solid state image pickup device of the respective embodiments as the image pickup device 4100, the image pickup system 4000 of the present embodiment can further improve distance measurement accuracy.

In the above description, although an example of performing control so that a vehicle does not collide with other vehicles has been described, the present invention can be applied to automated drive control for traveling so as to follow another vehicle and automated drive control for traveling so as not to deviate from a lane. The image pickup system is not limited to a vehicle such as an automobile but can be also applied to a mobile object (a movable device) such as a ship, an airplane, or an industrial robot. Furthermore, the present invention is not limited to be applied to a mobile object but can be broadly applied to an apparatus which uses object recognition, such as an intelligent transport system (ITS).

### Other Embodiments

The present invention is also realized by executing the following processes. That is, a program or a photographing recipe for realizing one or more functions of the respective embodiments is supplied to a system or an apparatus via a network or various storage media. One or more processors of a computer of the system or the apparatus read and execute the program or the photographing recipe. Moreover, the present invention can be also realized by a circuit (for example, an FPGA or an ASIC) that realizes one or more functions.

Embodiment(s) of the present invention can also be realized by a computer of a system or apparatus that reads out and executes computer executable instructions (e.g., one or more programs) recorded on a storage medium (which may also be referred to more fully as anon-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-009558, filed on Jan. 24, 2018, which is hereby incorporated by reference herein in its entirety.

What is claimed is:

1. An image pickup device comprising:
a semiconductor substrate including a pixel region in which pixels are arranged and a pad electrode region on which a pad electrode portion is disposed;
a wiring layer formed on the semiconductor substrate and including the pad electrode portion;
a planarizing layer formed on the wiring layer and formed in a portion upper than the pad electrode portion in the pad electrode region, the planarizing layer including an organic material; and
an inorganic film formed on the planarizing layer, wherein
an opening having a side wall portion is formed in the planarizing layer and the inorganic film so that an upper surface of the pad electrode portion is exposed, and
a metal film that covers at least a surface that forms the side wall portion of the planarizing layer is disposed in the opening.

2. The image pickup device according to claim 1, wherein
the metal film extended from the side wall portion is disposed in a direction along a surface of the semiconductor substrate from an uppermost portion of the side wall portion.

3. The image pickup device according to claim 2, wherein
a plurality of the pad electrode portions are disposed on the pad electrode region, and
the opening is formed for each of the plurality of pad electrode portions.

4. The image pickup device according to claim 3, wherein
the metal film includes a first section disposed in the side wall portion of the opening corresponding to one of the plurality of pad electrode portions and a second section disposed in the side wall portion of the opening corresponding to another one of the plurality of pad electrode portions, and
the first section and the second section are electrically insulated from each other.

5. The image pickup device according to claim 3, wherein
the metal film includes a first section disposed in the side wall portion of the opening corresponding to one of the plurality of pad electrode portions and a second section disposed in the side wall portion of the opening corresponding to another one of the plurality of pad electrode portions, and
the metal film further includes a section that electrically connects the first section and the second section.

6. The image pickup device according to claim 5, wherein
an insulating film that insulates the metal film from the pad electrode portion is disposed between the first section and the pad electrode portion and between the second section and the pad electrode portion.

7. The image pickup device according to claim 1, wherein
an inorganic insulating film is formed between the metal film and the side wall portion.

8. The image pickup device according to claim 7, wherein
the inorganic insulating film is a portion of the inorganic film.

9. The image pickup device according to claim 1, wherein
the semiconductor substrate forms a portion of the side wall portion of the opening.

10. The image pickup device according to claim 1, further comprising
a second inorganic film that covers the metal film.

11. The image pickup device according to claim 1, further comprising
a scribing region for dicing the semiconductor substrate, wherein
the metal film is also disposed in an opening formed in the scribing region.

12. The image pickup device according to claim 1, wherein
the planarizing layer is disposed on an upper layer and a lower layer of a color filter layer that contains dye in the pixel region.

13. The image pickup device according to claim 1, wherein
the metal film is a film formed of metal or a film that contains metal.

14. An image pickup device comprising:
a semiconductor substrate including a pixel region in which pixels are arranged and a pad electrode region on which a pad electrode portion is disposed; and
a photoelectric converting film formed on the semiconductor substrate and including an organic layer, wherein
an opening having a side wall portion is formed in the organic layer so that an upper surface of the pad electrode portion is exposed, and
a metal film that covers at least a surface that forms the side wall portion of the organic layer is disposed in the opening.

15. A display device comprising:
a semiconductor substrate including a pixel region in which pixels are arranged and a pad electrode region on which a pad electrode portion is disposed; and
an organic layer serving as an illuminating layer, formed on the semiconductor substrate, wherein
an opening having a side wall portion is formed in the organic layer so that an upper surface of the pad electrode portion is exposed, and
a metal film that covers at least a surface that forms the side wall portion of the organic layer is disposed in the opening.

16. The display device according to claim 15, wherein
the metal film extended from the side wall portion is disposed in a direction along a surface of the semiconductor substrate from an uppermost portion of the side wall portion,
a plurality of the pad electrode portions are disposed on the pad electrode region, and
the opening is formed for each of the plurality of pad electrode portions.

17. The display device according to claim 16, wherein
the metal film includes a first section disposed in the side wall portion of the opening corresponding to one of the plurality of pad electrode portions and a second section disposed in the side wall portion of the opening corresponding to another one of the plurality of pad electrode portions, and
the first section and the second section are electrically insulated from each other.

18. The display device according to claim 16, wherein
the metal film includes a first section disposed in the side wall portion of the opening corresponding to one of the plurality of pad electrode portions and a second section disposed in the side wall portion of the opening corresponding to another one of the plurality of pad electrode portions, and
the metal film further includes a section that electrically connects the first section and the second section.

19. An image pickup system comprising:
the image pickup device according to claim 1; and
a signal processing unit that processes signals output from the image pickup device.

20. A mobile object comprising:
the image pickup device according to claim 1;
distance information acquisition unit that acquires distance information to an object from signals output from pixels of the image pickup device; and
control unit that controls the mobile object on the basis of the distance information.
